(19) United States
(12) Patent Application Publication
(10) Pub. No.: US 2012/0212249 A1
(43) Pub. Date: Aug. 23, 2012

(54) HARD AND WEAR-RESISTING PROBE AND MANUFACTURING METHOD THEREOF

(75) Inventors: FONG JAY CHEN, HSIN-CHU CITY (TW); CHIU-FANG CHANG, HSIN-CHU CITY (TW)

(73) Assignee: KING YUAN ELECTRONICS CO., LTD, HSIN-CHU CITY (TW)

(21) Appl. No.: 13/207,348

(22) Filed: Aug. 10, 2011

(30) Foreign Application Priority Data
Feb. 23, 2011 (TW) 100105956

(51) Int. Cl. G01R 1/067; B22F 3/10; B22F 3/24; H01B 1/02

(52) U.S. Cl. 324/755.01; 252/503; 419/28

(57) ABSTRACT

The present invention relates to a hard and wear-resisting probe and manufacturing method thereof, and particularly relates to a hard and wear-resisting probe comprising tungsten steel (WC) and manufacturing method thereof. This hard and wear-resisting probe is substantially made of a tungsten steel with high hardness and wear resistance so that the probe is difficult to be worn and the lifetime of the probe is longer. Furthermore, the frequencies for changing the probe and the cost of testing are reduced, and the testing efficiency can be improved.

### CROSS-REFERENCE TO RELATED APPLICATIONS

The entire contents of Taiwan Patent Application No. 100105956, filed on Feb. 23, 2011, from which this application claims priority, are incorporated herein by reference.

### FIELD OF THE INVENTION

The present invention relates to a hard and wear-resisting probe and manufacturing method thereof, and particularly relates to a hard and wear-resisting probe comprising tungsten steel (WC) and manufacturing method thereof.

### BACKGROUND OF THE INVENTION

In the manufacturing process of semiconductor chips, before the semiconductor chips are packaged or shipped from the factory or Fab, a final test needs to be performed to each of the semiconductor chips to pick up the had semiconductor chips which are not detected before packaging or are damaged in the packaging process. Therefore, the quality of the semiconductor chips can be maintained. In this test (final test), a packaged semiconductor chip is put on a socket and the packaged semiconductor chip contacts test probes in order to receive the test signals for test.

Referring to FIGS. 1, 2 and 3 simultaneously, FIG. 1 is an explored diagram illustrating a conventional socket 10, FIG. 2 is an enlarged diagram illustrating the test probes 17 and the elastomers 20, 22 of the socket 10, and FIG. 3 is an enlarged and cross-section view diagram illustrating one side of the socket 10. FIG. 3 illustrates the cross-section structure of the socket 10 which is cut from one side of the socket 10 and along a line passing the center point of the socket 10. A guide plate 12, a frame 14 and several test probes 17 are stacked in order to form the socket 10. The opening 13 in center of the guide plate 12 is aligned with a cavity 15 in the center of the frame 14 to form a space which can hold a semiconductor chip for testing. There are several holes 16 corresponding to pads (not shown) of a semiconductor chip 24 in the cavity 15 and the test probes 17 are arranged to correspond to the holes 16. Therefore, fine tips 18 of the test probes 17 protrude from the holes 16 and the fine tips 18 can contact the pads of the semiconductor chip 24 for testing.

During testing, the semiconductor chip 24 is put in the space formed by the opening 13 of the guide plate 12 and the cavity 15 of the frame 14, and a pressure is applied on the semiconductor chip 24. Therefore, the pads of the semiconductor chip 24 contact the fine tips 18 of the test probes 17 closely, and even the fine tips 18 pierce through the oxide layers on the pads of the semiconductor chip 24 in order to contact the pads closely or directly pierce the pads of the semiconductor chip 24 for testing. At the same time, the elastomers 20 disposed under the middle of the test probes 17 and the elastomers 22 disposed above the tail of the test probes 17 force the fine tips to raise up for closely contacting the pads of the semiconductor chip 24. After testing is finished, the semiconductor chip 24 is picked up and another semiconductor chip is put in the socket 10 and the foregoing steps are repeated for testing.

During testing, all of the movements of picking up and placing the semiconductor chip, applying a pressure to the semiconductor chip for closely contacting the fine tips 18, and forcing the fine tips 18 of the test probes 17 to raise up for closely contacting the semiconductor chip cause the contact and the friction between the semiconductor chip and the fine tips 18. Therefore, the test probes are damaged because the contact and the friction, and particularly the fine tips 18 of the test probes 17. The hardness and wear resistance of the test probes are relatively low because the test probes are usually made of copper (Cu), tin, NiPdAu, etc. Therefore, it causes the test probes to be wear more easily and to have short service life (or lifetime). After a large amount of test, generally 350,000 times-500,000 times, the test probes 17 (particularly the fine tips 18) will be worn seriously and the semiconductor chip cannot contact the test probes 17 closely, and even the semiconductor chip cannot contact the test probes 17. Therefore, it results in short between the semiconductor chip 24 and the test probes 17, and it further results in fail tests. At this time, it has a need of shutting down the tester for checking the tester or changing the test probes. Therefore, the efficiency of testing is decreased because of the need to waste time to check the tester or change the test probes 17, and the cost of testing is increased because of the need to change the worn test probes frequently.

Furthermore, after a period of testing, the test probes 17 disposed at different locations of the socket 10 are worn to different degrees and the coplanarity of the test probes 17 get worse. It means that the test probes 17 disposed at different locations of the socket 10 have different height because the wearing degrees of the test probes 17 at different locations of the socket 10 are different. It causes the semiconductor chip to be inclined in the socket 10 and to be scraped and damaged by the test probes 17 while testing, or it causes that only parts of the pads of the semiconductor chip can contact the test probes closely. Therefore, a good test circuit between the semiconductor chip and the tester cannot be provided during testing, and it results in a fail test and low accuracy of the test. At this time, it has a need to shut down the tester for checking the wearing degrees of the test probes disposed at different locations of the socket by a user and for adjusting the coplanarity of the test probes by humans. And even, it has a need to change the test probes which are worn. Foregoing movements are time-consuming and strenuous. Therefore, the costs of manpower and time are increased and the efficiency of the test is decreased.

Furthermore, for some special semiconductor chips, there is a need to pierce through the oxide layers of these semiconductor chips. The conventional test probes 17 have lower hardness and lower wearing-resistance because of the material which the conventional test probes 17 are made of. Therefore, the conventional test probes 17 may be not hard enough to pierce through the oxide layers of these semiconductor chips or the conventional test probes 17 cannot pierce through the oxide layers of these semiconductor chips with enough depth. In these situations, the conducting ability between the test probes and the pads of these semiconductor chips is influenced and this influence results in an inaccurate test or a fail test.

Besides, as the number of testing times is increased, the wearing degree of the test probes 17 will also increase because the test probes 17 have lower hardness and wearing-resistance. It means that the parts of test probes 17 (or the fine tips 18) protruding from the frame 14 become smaller and so there is a need of a larger pressure implemented to the semiconductor chip for pressing the semiconductor chips lower to ensure the semiconductor chip contacting the test probes 17 closely. This movement results in larger force (or pressure) which is sustained by the elastomers 20 disposed under the middle of the test probes 17 and the elastomers 22 disposed above the tail of the test probes 17. Therefore, after time goes by, the elastomers 20, 22 have lost their elasticity because of suffering the continued force (or pressure) and so, these elastomers 20, 22 cannot provide enough force to raise the test probes upwardly. It results in had contacts between the test probes and the pads of the semiconductor chip and the bad contacts will result in an inaccurate test or a fail test. At this time, the tester needs to be shut down for checking or changing the test probes 17 and elastomers 20, 22. Therefore, not only the costs of manpower, time and materials are increased but the efficiency of testing are reduced.

Therefore, in view of the foregoing drawbacks of the conventional test probe, there is a need to provide a hard and wear-resisting probe. This hard and wear-resisting probe has the advantages of high hardness, high wear resistance and longer service life, and the probe of this invention can efficiently pierce through the oxide layers on the pads of the semiconductor chip for improving the conducting ability between the test probes and the pads and for reducing the times and frequency of changing the test probes and elastomers. Therefore, the costs of manpower, time and materials can be reduced and the efficiency of the test can be improved.

### SUMMARY OF THE INVENTION

An objective of this invention is to provide a hard and wear-resisting probe. This hard and wear-resisting probe has the advantages of high hardness, high wear resistance and longer service life (or lifetime), and the probe of this invention can efficiently pierce through the oxide layers on the pads of the semiconductor chip for improving the conducting ability between the test probes and the pads and for reducing the times and frequency of changing the test probes and elastomers. Therefore, the costs of manpower, time and materials can be reduced and the efficiency of the test can be improved.

Another objective of this invention is to provide a method for manufacturing a hard and wear-resisting probe. This method can manufacture a hard and wear-resisting probe having the advantages of high hardness, high wear resistance and longer service life. Therefore, the frequency and times of changing are reduced and the efficiency of the test is improved by using this hard and wear-resisting probe.

For one objective of this invention, a hard and wear-resisting probe is provided in this invention, and particularly a wear-resisting probe for testing packaged semiconductor chips is provided in this invention. This hard and wear-resisting probe comprises 75-96% weight percentage (wt %) of tungsten steel (WC) for improving the hardness of the hard and wear-resisting probe and 4-25% weight percentage (wt %) of cobalt (Co) which is used as a bonding agent for controlling the hardness of the hard and wear-resisting probe. The probe of this invention is harder than the conventional test probe which is made of copper (Cu), tin, NiPdAu, etc. because the probe of this invention is mainly made of tungsten steel (WC) which has the qualities of high hardness and high wear resistance. Therefore, during testing, the wearing and damage of the probe, which caused by the contact and friction between the probe and the semiconductor chip, can be avoided efficiently. It results in substantial increase of service life and reduction of frequency and times for changing the probe. Therefore, the costs of manpower, time and materials can be reduced and the efficiency of the test can be improved.

For another objective of this invention, a method for manufacturing a hard and wear-resisting probe is provided. This method is provided to manufacture a probe which has the qualities of high hardness, high wear resistance, long service life (or lifetime), and low frequency (or times) of changing test probes and elastomers and is used for testing semiconductor chips which have already been packaged. This method for manufacturing a hard and wear-resisting probe comprises the following steps. First, metal powders for manufacturing the probe, for example powders of tungsten steel (WC) and powders of cobalt (Co), are mixed and then the mixed metal powders are sintered to form a metal plate. Next, the metal plate is ground to a predetermined thickness, and then, the ground metal plate is cut to form a probe having a predetermined shape. Finally, the cut probe is trimmed in order to get the hard and wear-resisting probe of this invention. Therefore, this probe manufactured by this method can have the advantages of high hardness, high wear resistance, longer service life (or lifetime), and low frequency (or times) of changing test probes and elastomers.

Therefore, the effect achieved with the present invention is to provide a hard and wear-resisting probe and manufacturing method thereof, and particularly to provide a probe for performing a test (final test) to semiconductor chips which have already been packaged. This probe has the qualities of high hardness, high wear resistance, and long service life (or lifetime) and the probe also has advantages of decrease of frequency and times for changing test probes and elastomers, decrease of costs of manpower, time and materials, and increase of testing efficiency.

### BRIEF DESCRIPTION OF THE DRAWINGS

FIG. 1 is an explored diagram illustrating a conventional socket.

FIG. 2 is an enlarged diagram illustrating the test probes and the elastomers of the conventional socket shown in FIG. 1.

FIG. 3 is an enlarged and cross-section view diagram illustrating one side of the conventional socket shown in FIG. 1.

FIG. 4 is a flow chart illustrating a method for manufacturing a hard and wear resisting probe in accordance with one embodiment of the present invention.

### DESCRIPTION OF THE EXEMPLARY EMBODIMENTS

Although the present invention is described in accordance with the embodiments shown as follows, one of ordinary skill in the art will readily recognize that there could be variations to the embodiments and those variations would be within the spirit and scope of the present invention. Accordingly, many modifications may be made by one of ordinary skill in the art without departing from the spirit and scope of the invention as limited only by the appended claims.

A hard and wear-resisting probe is provided in this invention, and particularly, a probe for final test of packaged semiconductor chips, which replaces the probe made of copper (Cu), tin, or NiPdAu. This hard and wear-resisting probe is a probe mainly made of tungsten steel (WC) having qualities of high hardness and high wear resistance. The hard and wear-resisting probe comprises 75-96% weight percentage (wt %) of tungsten steel (WC) for improving the hardness of the hard and wear-resisting probe and 4-25% weight percentage (wt %) of cobalt (Co) which is used as a bonding agent for controlling the strength of the hard and wear-resisting probe, for example bending strength, compressive strength and impact strength.

The tungsten steel (WC) is a material having qualities of high hardness and high wear resistance. Therefore, the more tungsten steel the probe of this invention has, the harder and the more wear-resisting the probe of this invention is. It means that the higher weight percentage (wt %) of tungsten steel (WC) the probe of this invention comprises, the higher hardness and better wear resistance the probe of this invention has. However, a harder material often has qualities of lower bending strength, lower compressive strength and lower impact strength. Therefore, the bending strength, the compressive strength and the impact strength of the probe are decreased as the proportion of tungsten steel (WC) in the probe is increased. On the contrary, the bending strength, the compressive strength and the impact strength of the probe are increased as the proportion of cobalt (Co) in the probe is increased. But the hardness and the wear resistance of the probe are decreased as the proportion of cobalt (Co) in the probe is increased. In this invention, the proportion of tungsten steel (WC) for forming the probe can be adjusted in range of 75-96% weight percentage (wt %) and the proportion of cobalt (Co) for forming the probe can be adjusted in range of 4-25% weight percentage (wt %) according to the required hardness, the required wear resistance, the required bending strength, the required compressive strength and the required impact strength of the probe. For example, in one preferred embodiment, the probe comprises 82% weight percentage (wt %) of tungsten steel (WC) and 18% weight percentage (wt %) of cobalt (Co). Therefore, the probe has 90.0 HRA of hardness, 400 kgf/mm² of bending strength, 400 kgf/mm² of compressive strength, and 0.85 kgf/cm² of impact strength in this preferred embodiment.

Furthermore, the hard and wear-resisting probe of this invention may comprise carbon (C) for improving the hardness and the hot hardness of the hard and wear-resisting probe. The hard and wear-resisting probe may comprise 0.5-1.5% weight percentage (wt %) of carbon (C). The hardness and the hot hardness of the hard and wear-resisting probe are further increased by addition of carbon (C). Next, the hard and wear-resisting probe may further comprise chromium (Cr) for improving the wear resistance of the hard and wear-resisting probe. The hard and wear-resisting probe may comprise 0.5-3% weight percentage (wt %) of chromium (Cr). The wear resistance of the hard and wear-resisting probe is further increased by addition of chromium (Cr). Furthermore, the hard and wear-resisting probe may further comprise aluminum (Al) for improving the hot hardness of the hard and wear-resisting probe. The hard and wear-resisting probe may comprise 0.5-1% weight percentage (wt %) of aluminum (Al). The hot hardness of the hard and wear-resisting probe is further increased by addition of aluminum (Al).

In embodiments of this invention, one, two or all of the materials of carbon (C), chromium (Cr) and aluminum (Al) can be adopted according to the required hardness, the required wear resistance, the required bending strength, the required compressive strength and the required impact strength of the probe. It means that the hard and wear-resisting probe may simultaneously comprise 0.5-1.5% weight percentage (wt %) of carbon (C), 0.5-3% weight percentage (wt %) of chromium (Cr) and 0.5-1% weight percentage (wt %) of aluminum (Al) in one embodiment of this invention. It is worth noting that the weight percentage (wt %) of carbon (C), chromium (Cr) and aluminum (Al) cannot be higher or lower than the above-mentioned weight percentage (wt %) ranges of carbon (C), chromium (Cr) and aluminum (Al). Therefore, it can avoid decreasing of the physical qualities of the hard and wear-resisting probe, such as the bending strength, the compressive strength and the impact strength.

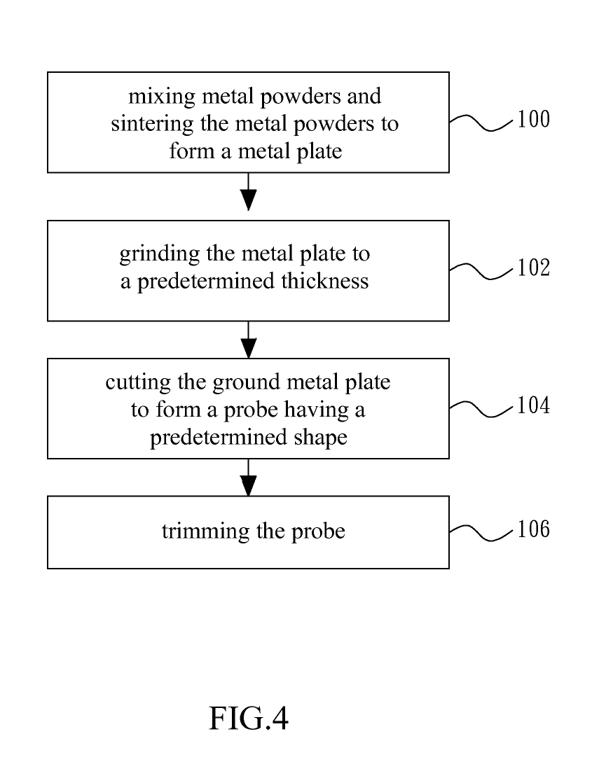

Besides, a method for manufacturing a hard and wear-resisting probe is provided in this invention. Referring to FIG. 4, it is a flow chart illustrating a method for manufacturing a hard and wear-resisting probe in accordance with one embodiment of the present invention. First, metal powders which are above-mentioned materials for manufacturing the hard and wear-resisting probe are mixed. These metal powders mainly comprise 75-96% weight percentage (wt %) of tungsten steel (WC) powder and 4-25% weight percentage (wt %) of cobalt (Co) powder. Furthermore, one, two or all of the carbon (C) powder, chromium (Cr) powder and aluminum (Al) powder may be selectively added into the metal powders according to the required hardness, the required wear resistance, the required bending strength, the required compressive strength and the required impact strength of the hard and wear-resisting probe. Next, these metal powders are sintered at 1400-2000° C. to form a metal plate (step 100). In one preferred embodiment of this invention, the metal powders are sintered at 1400° C. In one preferred embodiment, metal plate is sintered in form of ultrafine particles. Therefore, the hard and wear-resisting probe can have 0.6-0.7 μm of the granularity. The thickness of the metal plate sintered by the metal powders is in the range of 0.3-0.7 mm, and in one preferred embodiment, the thickness of the metal plate is 0.5 mm.

After, the metal plate is ground to a predetermined thickness (step 102). The thickness of the metal plate is determined according to the design of the probe and the required shape and structure of the probe. The thickness of the metal plate is in the range of 0.1-0.2 mm and in one preferred embodiment, the predetermined thickness is 0.17 mm.

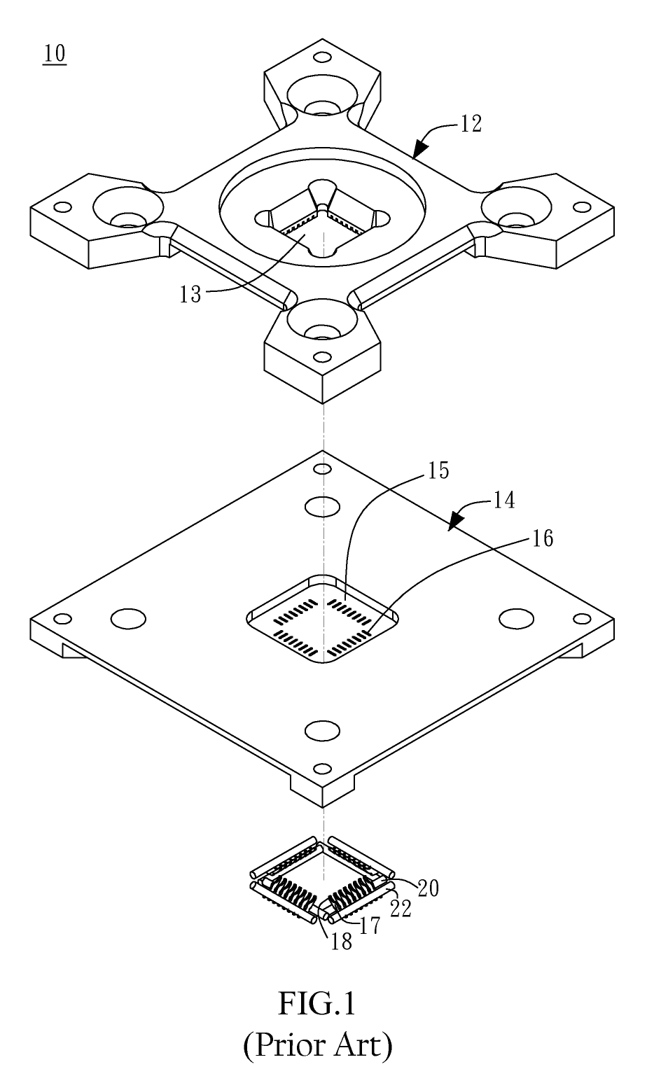

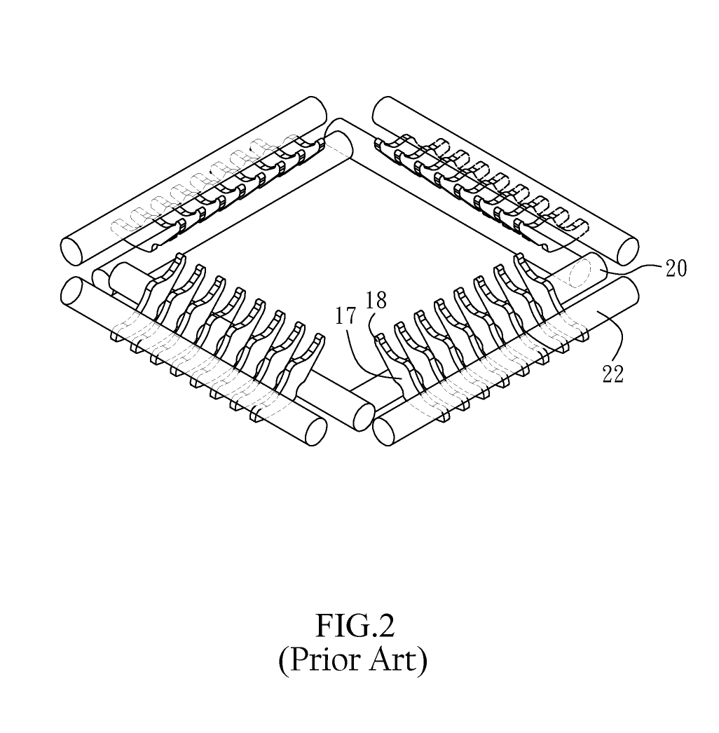

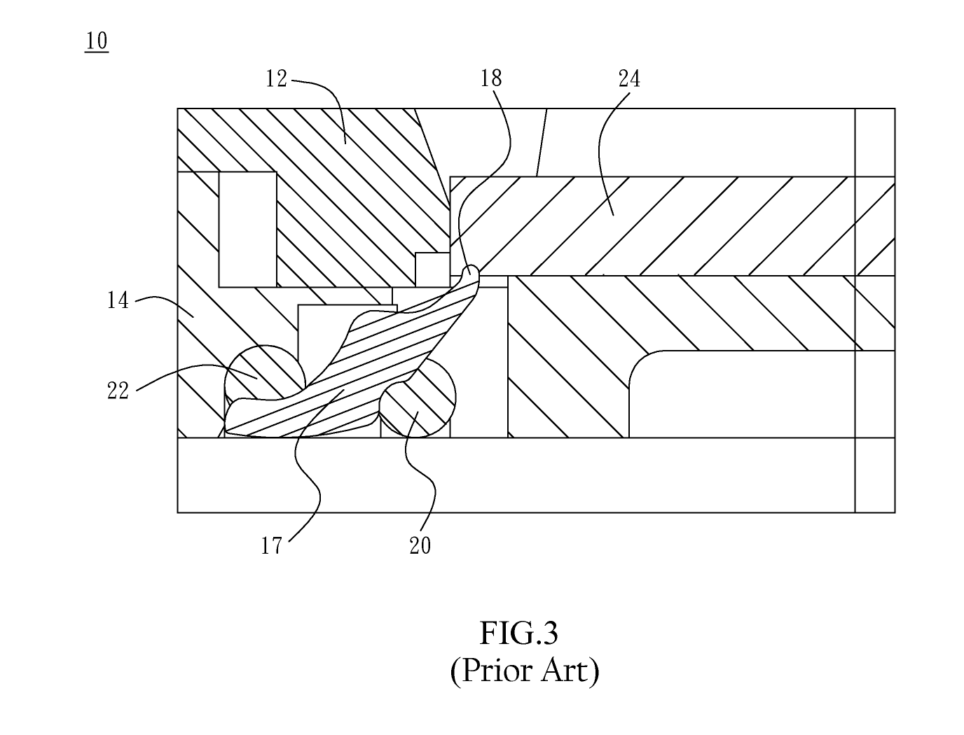

And then, according to the design of the probe and the required shape and structure of the probe, the metal plate which is ground is cut to form a probe having a predetermined shape (step 104), for example the probe has the same shape with the shape of the conventional probe shown in FIGS. 1-3, the shape of pogo pin, the shape of the fine tip of the pogo ping, or shapes of the other probes. In step 104, the ground metal plate is cut to form a probe having a predetermined shape by wire cut or other techniques.

Finally, the probe is trimmed for removing the burrs of the probe which may influence the test (step 106). As a result, a hard and wear-resisting probe for final test of semiconductor chips or for test (or final test) of semiconductor chip which have been packaged is produced.

The hard and wear-resisting probe, which is manufacturing by above-mentioned composition and the manufacturing method, is mainly made of tungsten steel (WC) with high hardness and high wear resistance (comprising 75-96% weight percentage (wt %) of tungsten steel (WC)). Therefore, the hard and wear-resisting probe of this invention is harder and more wear-resisting than the conventional probe made of the materials of Cu, Tin or NiPdAu. As a result, the hard and wear-resisting probe has a much longer service life (or lifetime) than the conventional probe. Furthermore, cobalt (Co) is used as the secondary material for manufacturing the hard and wear-resisting probe (comprising 4-25% weight percentage (wt %) of cobalt (Co)). Therefore, the hard and wear-resisting probe has much higher hardness and higher wear resistance than the conventional probe, and it has the same physical quality with the conventional probe or better physical quality than the conventional probe, for example the bending strength, the compressive strength, and impact strength. Besides, the hardness, the wear resistance, and the hot hardness of the hard and wear-resisting probe are improved by addition of carbon (C), chromium (Cr) and aluminum (Al) (one, two, or all of them are selectively added to form the probe).

Therefore, the hard and wear-resisting probe, which is manufacturing by above-mentioned composition and the manufacturing method, has 80-95 HRA of hardness, 290 kgf/mm² of bending strength or larger bending strength than 290 kgf/mm², 290 kgf/mm² of compressive strength or larger compressive strength than 290 kgf/mm², 0.20 kgf/cm² of impact strength or larger impact strength than 0.20 kgf/mm², and 0.6-6 μm of the granularity. Accordingly, the probe of this invention has higher hardness and higher wear resistance than the conventional probe made of Cu, Tin, or NiPdAu has. Besides, the strength of the probe of this invention is at least equal to or larger than the strength of the conventional probe, such as bending strength, compressive strength, impact strength.

The hard and wear-resisting probe is not easy to be worn by contact and friction caused by testing because this probe is much harder and more wear-resisting than the conventional probe. Therefore the hard and wear-resisting probe has longer service life for lifetime). The hard and wear-resisting probe may be worn or worn to cause bad influence during testing after at least 900,000 times of testing. In some embodiments, the probe may be worn or worn to cause bad influence during testing after at least 1,500,000 times of testing. Accordingly, the service life (lifetime) of the probe is much longer than the service life (lifetime) of the conventional probe which is worn or worn to cause bad influence during testing after 350,000-500,000 times of testing. Therefore, comparing with the conventional probe, the times and frequencies of changing the probe are decreased by using the probe of this invention during testing. Furthermore, the required costs of manpower, time and materials are decreased. The efficiency of the test is increased because the times and frequencies of shutting down the tester for checking and changing probes are reduced.

Because the hard and wear-resisting probe of this invention is harder and more wear-resisting, after 900,000 times of testing or even after 1,500,000 times of testing, the probe is worn or broken enough to influence testing, for example the coplanarity of probes get worse. Therefore, before at least 900,000 times of testing (or before 1,500,000 times of testing in some embodiments), there is no need to shut down the tester for adjusting the coplanarity of probes and for changing worn or broken probes. The required costs of manpower, time and materials for adjusting the coplanarity of probes and changing worn or broken probes can be decreased. The efficiency of the test can be increased because the times and frequencies of shutting down the tester for adjusting the coplanarity of probes and changing worn or broken probes are reduced. Similarly, incline of the semiconductor chip in a socket caused by the worse coplanarity and scratches and damages caused by the incline will not happen because the probe of this invention is hard and wear-resisting enough to prevent the probes and the coplanarity of the probes from being worn and getting worse.

In this invention, there is no need to implement a larger pressure to the semiconductor chip for pressing the semiconductor chips lower to ensure the semiconductor chip contacting the probes closely. It is because the hard and wear-resisting probe of this invention is much harder and wear-resisting than the conventional probe and this probe is harder and wear-resisting enough to present from wearing of the probe. Therefore, the circuit between the pads of the semiconductor chip and the probes will be formed well and the conducting ability between the probes and the pads of the semiconductor chip will not be influenced. By using the probe of this invention, there is no need to overly implement a force (or pressure) to the elastomers disposed under the middle of the probes and the elastomers disposed above the tail of the probes and the elastomers are not fatigued because of the continued force (or pressure). Therefore, there is no need to shut down tester and change the probes frequently and the required costs of manpower, time and materials for checking and changing worn or broken probes can be decreased. Furthermore, the times and frequencies of shutting down the tester for checking and changing probes can be reduced and so, the efficiency of the test can be increased.

The hard and wear-resisting probe of this invention is hard enough to pierce through most of oxide layers of semiconductor chips because it is much harder and wear-resisting than the conventional probe. It make the probe of this invention to be able to efficiently pierce through the pads of the semiconductor chips and contact to the pads closely for increasing conducting ability between the probes and the pads. Therefore, it can avoid an inaccurate test or a fail test caused by the situation that the probe cannot pierce through the pads or depth pierced through by the probe is not enough.

Furthermore, the hard and wear-resisting probe mainly made of tungsten steel (WC) has good conducting ability because tungsten steel (WC) is a material with good conducting ability. Therefore, there is no need to electroplate the surface of the probe with a metal having good conducting ability (such as gold (Au)) as the conventional probe which is made of copper (Cu) or other metal with bad conducting ability. Therefore, the cost for manufacturing the probe can be decreased and the process for manufacturing the probe can be simplified.

Therefore, a hard and wear-resisting probe and manufacturing method thereof are provided in this invention. This hard and wear-resisting probe has the advantages of high hardness, high wear resistance and longer service life (or lifetime), and the probe of this invention can efficiently pierce through the oxide layers on the pads of the semiconductor chip for improving the conducting ability between the test probes and the pads and for reducing the times and frequency of changing the test probes and elastomers. Therefore, the costs of manpower, time and materials can be reduced and the efficiency of the test can be improved.

What is claimed is:

1. A hard and wear-resisting probe, comprising:
75-96% weight percentage (wt %) of tungsten steel (WC) for improving the hardness of said hard and wear-resisting probe; and
4-25% weight percentage (wt %) of cobalt (Co) wherein said cobalt is used as a bonding agent for controlling the hardness of said hard and wear-resisting probe.

2. The probe of claim 1, wherein said hard and wear-resisting probe comprises 82% weight percentage (wt %) of tungsten steel (WC).

3. The probe of claim 2, wherein said hard and wear-resisting probe comprises 18% weight percentage (wt %) of cobalt (Co).

4. The probe of claim 1, wherein said hard and wear-resisting probe further comprises carbon (C) for improving the hardness and the hot hardness of said hard and wear-resisting probe.

5. The probe of claim 4, wherein said hard and wear-resisting probe comprises 0.5-1.5% weight percentage (wt %) of carbon (C).

6. The probe of claim 1, wherein said hard and wear-resisting probe further comprises chromium (Cr) for improving the wear resistance of said hard and wear-resisting probe.

7. The probe of claim 6, wherein said hard and wear-resisting probe comprises 0.5-3% weight percentage (wt %) of chromium (Cr).

8. The probe of claim 1, wherein said hard and wear-resisting probe further comprises aluminum (Al) for improving the hot hardness of said hard and wear-resisting probe.

9. The probe of claim 8, wherein said hard and wear-resisting probe comprises 0.5-1% weight percentage (wt %) of aluminum (Al).

10. The probe of claim 1, wherein said hard and wear-resisting probe further comprises materials of carbon (C), chromium (Cr), and aluminum (Al).

11. The probe of claim 10, wherein said hard and wear-resisting probe further comprises 0.5-1.5% weight percentage (wt %) of carbon (C), 0.5-3% weight percentage (wt %) of chromium (Cr), and 0.5-1% weight percentage (wt %) of aluminum (Al).

12. The probe of claim 1, wherein a method for manufacturing said hard and wear-resisting probe comprises:
mixing metal powders and sintering metal powders to form a metal plate;
grinding said metal plate to a predetermined thickness;
cutting said ground metal plate to form a probe having a predetermined shape; and
trimming said probe.

13. The probe of claim 12, wherein said metal plate is sintered in form of ultrafine particles.

14. The probe of claim 13, wherein said metal powders are sintered at 1400-2000° C. to form said metal plate.

15. The probe of claim 14, wherein said metal powders are sintered at 1400° C. to form said metal plate.

16. The probe of claim 14, wherein said step of cutting said ground metal plate to form a probe having a predetermined shape is performed by wire cut.

17. The probe of claim 1, wherein said hard and wear-resisting probe is used for final test or used for testing chips which are packaged.

18. The probe of claim 17, wherein said hard and wear-resisting probe is a pogo pin.

19. A method for manufacturing a hard and wear-resisting probe, comprising:
mixing metal powders and sintering metal powders to form a metal plate;
grinding said metal plate to a predetermined thickness;
cutting said ground metal plate to form a probe having a predetermined shape; and
trimming said probe.

20. The method of claim 19, wherein said metal plate is sintered by in form of ultrafine particles.

21. The method of claim 20, wherein said metal powders are sintered at 1400-2000° C. to form said metal plate in said step of sintering metal powders to form a metal plate.

22. The method of claim 21, wherein said metal powders are sintered at 1400° C. to form said metal plate in said step of sintering metal powders to form a metal plate.

23. The method of claim 19, wherein said step of cutting said ground metal plate to form a probe having a predetermined shape is performed by wire cut.

24. The method of claim 19, wherein said metal powders comprise 75-96% weight percentage (wt %) of tungsten steel (WC) for improving the hardness of said hard and wear-resisting probe and 4-25% weight percentage (wt %) of cobalt (Co) wherein said cobalt is used as a bonding agent for controlling the hardness of said hard and wear-resisting probe.

25. The method of claim 24, wherein said metal powders further comprise 0.5-1.5% weight percentage (wt %) of carbon (C).

26. The method of claim 24, wherein said metal powders further comprise 0.5-3% weight percentage (wt %) of chromium (Cr).

27. The method of claim 24, wherein said metal powders further comprise 0.5-1% weight percentage (wt %) of aluminum (Al).

28. The method of claim 24, wherein said metal powders further comprise 0.5-1.5% weight percentage (wt %) of carbon (C), 0.5-3% weight percentage (wt %) of chromium (Cr), and 0.5-1% weight percentage (wt %) of aluminum (Al).
